(19) United States
(12) Patent Application Publication
(10) Pub. No.: US 2020/0158791 A1
(43) Pub. Date: May 21, 2020

(54) SENSOR PACKAGE WITH INTEGRATED MAGNETIC SHIELD STRUCTURE

(71) Applicant: NXP B.V., Eindhoven (NL)

(72) Inventors: Stephan Marauska, Kaltenkirchen (DE); Dennis Helmboldt, Halstenbek (DE); Bernd Offermann, Hamburg (DE); Thomas Hain, Buchholz (DE)

(21) Appl. No.: 16/191,694

(22) Filed: Nov. 15, 2018

(51) Int. Cl. G01R 33/00; G01D 5/16; H01L 43/08; H01L 43/12; H01L 43/02

(52) U.S. Cl. CPC G01R 33/0076; G01R 33/0047; H01L 43/02; H01L 43/08; H01L 43/12; G01D 5/16

(57) ABSTRACT

A sensor package includes a magnetic field sensor having first and second surfaces, the first surface being a sensing surface of the magnetic field sensor, a shield structure spaced apart from the magnetic field sensor, and a spacer interposed between the magnetic field sensor and the shield structure. The shield structure is configured to suppress stray magnetic fields in a plane parallel to first and second axes that are parallel to the sensing surface of the magnetic field sensor and perpendicular to one another. The shield structure may include a continuous sidewall having a central region, the spacer being surrounded by the continuous sidewall and the sensing surface of the magnetic field sensor being positioned outside of the central region. A system includes an encoder magnet and the sensor package, with the sensing surface of the magnetic field sensor facing the encoder magnet.

### TECHNICAL FIELD OF THE INVENTION

The present invention relates generally to magnetic field sensors. More specifically, the present invention relates to sensor packages with integrated magnetic structures for measuring magnetic fields while suppressing stray magnetic fields.

### BACKGROUND OF THE INVENTION

Magnetic field sensor systems are utilized in a variety of commercial, industrial, and automotive applications to measure magnetic fields for purposes of speed and direction sensing, rotation angle sensing, proximity sensing, and the like. A technique for measuring an angular position (e.g., for throttle valves, pedals, steering wheels, brushless direct current (BLDC) motors, and so forth) is to mount an encoder magnet onto a rotation element and detect an orientation of the encoder magnet using one or more magnetic field sensor components. In an angular measurement application, a stray magnetic field along a sensing axis of the magnetic field sensor may be superimposed on the signals of interest, thus causing errors in the detection of angular position.

### BRIEF DESCRIPTION OF THE DRAWINGS

The accompanying figures in which like reference numerals refer to identical or functionally similar elements throughout the separate views, the figures are not necessarily drawn to scale, and which together with the detailed description below are incorporated in and form part of the specification, serve to further illustrate various embodiments and to explain various principles and advantages all in accordance with the present invention.

FIG. 1 shows a simplified partial side view of a prior art system for rotation angle sensing;

FIG. 2 shows a graph demonstrating angular relations for magnetic field vectors in the presence of the unwanted stray magnetic field;

FIG. 3 shows a simplified partial side view of a system for rotation angle sensing in accordance with an embodiment;

FIGS. 4A-C show top, side, and front views, respectively, of a sensor package in accordance with an embodiment;

FIGS. 5A-C show top, side, and front views, respectively, of a sensor package in accordance with another embodiment;

FIGS. 6A-C show simplified top, side, and front views, respectively, of a sensor package in accordance with another embodiment;

FIGS. 7A-C show simplified top, side, and front views, respectively, of a sensor package in accordance with another embodiment;

FIGS. 8A-C show simplified top, side, and front views, respectively, of a sensor package in accordance with another embodiment;

FIGS. 9A-C show simplified top, side, and front views, respectively, of a sensor package in accordance with another embodiment;

FIGS. 10A-C show simplified top, side, and front views, respectively, of a sensor package in accordance with another embodiment;

FIGS. 11A-C show simplified top, side, and front views, respectively, of a sensor package in accordance with another embodiment;

FIGS. 12A-C show simplified top, side, and front views, respectively, of a sensor package in accordance with another embodiment;

FIGS. 13A-C show simplified top, side, and front views, respectively, of a sensor package in accordance with another embodiment;

FIGS. 14A-C show simplified top, side, and front views, respectively, of a sensor package in accordance with another embodiment;

FIGS. 15A-C show simplified top, side, and front views, respectively, of a sensor package in accordance with another embodiment; and

FIG. 16 shows a flowchart of a process for manufacturing a sensor package with an integrated magnetic shield structure in accordance with another embodiment.

### DETAILED DESCRIPTION

In overview, the present disclosure concerns sensor packages with integrated magnetic shield structures for measuring magnetic fields while suppressing stray magnetic fields. More particularly, a sensor package includes one or more magnetic field sensors partially encompassed by a magnetic field shield structure. The geometric configuration of the shield structure and the location of the shield structure within a sensor package can be varied to provide shielding or suppression of stray magnetic fields with minor or little adverse impact to the measurement magnetic field acting on magnetic sensor components. Further, the shield structure can be formed as a separate structure from the magnetic field sensors to enable straightforward incorporation into a sensor package. The position of the shield structure in relation to the magnetic field sensors, therefore, may enable sufficient shielding of the stray magnetic fields without unduly suppressing the magnetic field from, for example, an encoder magnet. Accordingly, a compromise may be achieved between optimal passive stray field suppression (with no additional electronic circuitry) and cost-effective, accurate manufacturing options. Still further, the magnetic field sensor package can be integrated in various system configurations to satisfy automotive requirements in, for example, throttle valves, pedals, steering wheels, brushless direct current (BLDC) motors, and so forth.

The instant disclosure is provided to further explain in an enabling fashion at least one embodiment in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It should be understood that the use of relational terms, if any, such as first and second, top and bottom, and the like are used solely to distinguish one from another entity or action without necessarily requiring or implying any actual such relationship or order between such entities or actions. Furthermore, some of the figures may be illustrated using various shading and/or hatching to distinguish the different elements produced within the various structural layers. These different elements within the structural layers may be produced utilizing current and upcoming microfabrication techniques of depositing, patterning, etching, and so forth. Accordingly, although different shading and/or hatching is utilized in the illustrations, the different elements within the structural layers may be formed out of the same material.

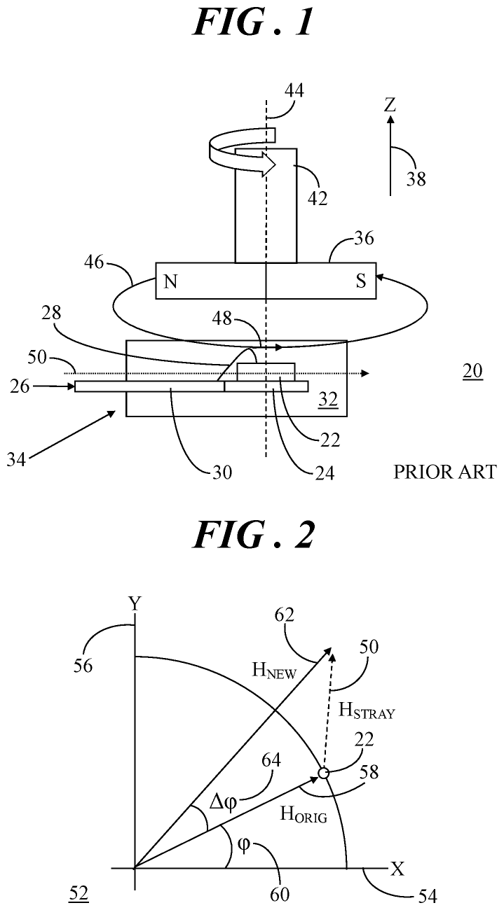

Referring to FIG. 1, FIG. 1 shows a simplified partial side view of a prior art system 20 for rotation angle sensing. System 20 generally includes a magnetic field sensor 22 (e.g., a magnetic field sensor die) attached to a die pad 24 of a lead frame 26. Bond wires 28 (one shown) may electrically connect magnetic field sensor 22 to leads 30 (one shown) of lead frame 26. Magnetic field sensor 22, lead frame 26, and bond wires 28 may be encapsulated in a mold compound 32 (which can provide environmental protection for magnetic field sensor 22) to form a sensor package 34. A magnet 36 is vertically displaced away from magnetic field sensor 22 along a Z-axis 38, within a three-dimensional coordinate system. Magnet 36 may be glued or otherwise attached to a rotatable object 42 such as an axle, shaft, and the like. Thus, rotatable object 42 and magnet 36 (by virtue of its attachment to rotatable object 42) are configured to rotate about an axis of rotation 44 relative to magnetic field sensor 22.

In this example, magnet 36 may be a dipole magnet having a north pole (labeled N) on one side and a south pole (labeled S) on the other side. Magnet 36 may be a permanent magnet in the form of a cylinder, bar, disc, ring, or any other suitable shape. Magnet 36 produces a magnetic field 46 that rotates along with magnet 36 relative to magnetic field sensor 22. In this example configuration, magnetic field sensor 22 is vertically displaced below the center of magnet 36. Magnetic field sensor 22 may be a magnetoresistive device, such as an anisotropic magnetoresistance (AMR) sensor, giant magnetoresistance (GMR) sensor, tunnel magnetoresistance (TMR) sensor, or similar technology, that is configured to detect the direction of magnetic field 46 produced by magnet 36.

Magnetic field 46 has an in-plane component, denoted by an arrow 48, that is “seen” or detected by magnetic field sensor 22. In an ideal configuration, magnetic field sensor 22 only measures the in-plane magnetic field component 48 of magnetic field 46. However, magnetic field sensor 22 may also be exposed to an unwanted stray magnetic field 50, denoted by dotted lines. Stray magnetic fields (e.g., stray magnetic field 50) change the magnetic field being measured by magnetic field sensor 22, and therefore can introduce error into the measurement signal. Consequently, stray magnetic field 50 is sometimes referred to as an interference magnetic field.

Referring to FIGS. 1 and 2, FIG. 2 shows a graph 52 demonstrating angular relations for magnetic field vectors in the presence of the unwanted stray magnetic field 50. In particular, graph 52 shows vectors in a Cartesian coordinate system that includes an X-axis 54 and a Y-axis 56. In this example, magnetic field sensor 20 is operating in a saturation mode. In general, the saturation mode is when external magnetic fields (e.g., magnetic field 46) are above a certain field strength level (referred to as a saturation field). The magnetic moments in the magnetic field sensor are thus aligned in the same direction of the saturation field. Therefore, the output of the magnetic field sensor device reflects the direction (in particular, the angle) of the external magnetic field and not the field strength of the magnetic field.

In the saturation mode, a first vector 58, labeled H_{ORIG}, represents the direction of the magnetic field 46 from magnet 36 at the position of magnetic field sensor 22 in the absence of stray magnetic field 50. A rotation angle 60, labeled φ, thus represents a rotation angle value relative to an original position of magnet 36 where, for example, the original angular position of magnet 36 is zero and is aligned with X-axis 54. A second vector 62, labeled H_{NEW}, represents a detected magnetic field in the presence of stray magnetic field 50, labeled H_{STRAY}. Thus, second vector 62 represents a combination of H_{NEW} and the sensor response, H_{STRAY}, due to stray magnetic field 50. The presence of stray magnetic field 50 leads to an angular error 64, labeled Δφ. Angular error 64 may be wrongly interpreted to be an additional distance that magnet 36 has rotated. Thus, an error condition or inaccurate measurement ensues because a determination may be made that a rotation angle value for magnet 36 is the combination of the actual rotation angle 60 plus the angular error 64 (e.g., φ+Δφ). Therefore, in the magnetic field sensor configuration of FIG. 1, the effects of stray magnetic field 50 cannot be distinguished from the actual rotation of magnet 36. Consequently, neither detection of stray magnetic field 50 nor suppression may be accurately achieved from the output of magnetic field sensor 22 that provides only angular information in the saturation mode.

The discussion presented above in connection with FIGS. 1-2 pertains to a magnetoresistive magnetic field sensor operating in the saturation mode. Hall effect sensors, which have a linear response to only a single component of a magnetic field, are another commonly used magnetic field sensor technology for angular measurement. However, magnetoresistive sensor technologies, such as AMR, TMR, GMR, and the like, have some distinct advantages over Hall sensors. Magnetoresistive sensor technologies may achieve better noise performance than Hall effect sensors. Additionally, magnetoresistive sensors may be operated reliably at much higher temperatures relative to Hall effect sensors and it may be possible to achieve higher angular accuracies with magnetoresistive sensors relative to Hall effect sensors.

Some of these advantages may be obtained by operating a magnetoresistive sensor in a saturation mode for angular measurements. In the saturation mode, the sensor is almost only sensitive to the angle of the magnetic field (e.g., the field angle) and hardly to strength of the magnetic field (e.g., the field strength). The local magnetic field angle may therefore be measured relatively accurately, without being affected by magnetic field strength. One of the key challenges of implementing magnetoresistive sensor devices is the presence of disturbing magnetic fields of sources (e.g., stray magnetic field 50) other than the above-mentioned magnet 36. As demonstrated in graph 52, stray magnetic field 50 changes the magnetic field being measured by the magnetic field sensor, thereby compromising the accuracy of the measured rotation angle. Embodiments described below include sensor packages with integrated magnetic shield structures for achieving suppression of stray magnetic fields for magnetic field sensors, and in particular magnetoresistive and Hall sensors, operating in a saturation mode.

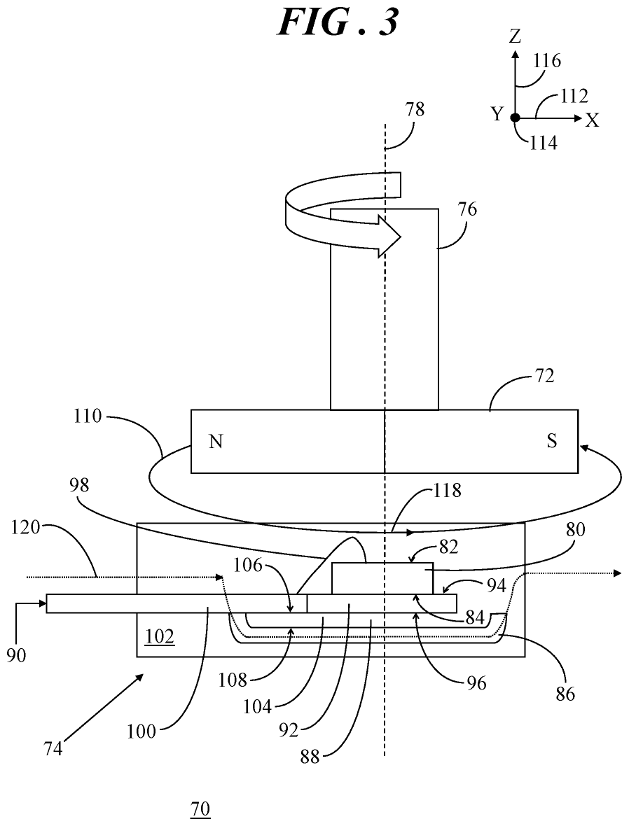

FIG. 3 shows a simplified partial side view of a system 70 for rotation angle sensing in accordance with an embodiment. In this illustrated configuration, system 70 includes a magnet 72 and a sensor package 74. Magnet 72 may be glued or otherwise attached to a rotatable object 76 such as an axle, shaft, and the like. Thus, rotatable object 76 and magnet 72 (by virtue of its attachment to rotatable object 76) are configured to rotate about an axis of rotation 78. Additionally, magnet 72 is a two pole diametrically magnetized magnet (e.g., magnetized through the diameter of the magnet) centered at axis of rotation 78.

Sensor package 74 includes a magnetic field sensor 80 (e.g., a magnetic field sensor die) having a first surface (referred to herein as a sensing surface 82) and a second surface 84, in which the second surface 84 is opposite the sensing surface 82. A shield structure 86 is spaced apart from second surface 84 of magnetic field sensor 80 and a spacer 88 is interposed between second surface 84 and shield structure 86. As such, shield structure 86 can be formed as a separate structure from magnetic field sensor 80. In the illustrated configuration, sensor package 74 further includes a lead frame 90 having a mounting area 92 (sometimes referred to as a die pad) characterized by a first side 94 and a second side 96, in which the second side 96 is opposite the first side 94. Second surface 84 of magnetic field sensor 80 is attached to first side 94 of mounting area 92. Bond wires 98 (one shown) may electrically connect magnetic field sensor 80 to leads 100 (one shown) of lead frame 90.

Magnetic field sensor 80, shield structure 86, mounting area 92 of lead frame 90, bond wires 98, and the ends of leads 100 to which bond wires 98 are attached may be encapsulated in a mold compound 102 to form sensor package 74. Hence, in the illustrated example, spacer 88 includes a portion 104 of mold compound 102 located between second side 96 of mounting area 92 of lead frame 90 and shield structure 86. Accordingly, a first side 106 of portion 104 (as spacer 88) of mold compound 102 in direct contact with second side 96 of mounting area 92 is coupled to lead frame 90. Shield structure 86 is thus coupled to a second side 108 of portion 104 (as spacer 88) of mold compound 102 in direct contact with shield structure 86.

Magnet 72 produces a magnetic field 110 that rotates with magnet 72 relative to magnetic field sensor 80. In this example configuration, magnetic field sensor 80 is vertically displaced below and is centered axis of rotation 78 and therefore is centered at the center of magnet 72. Magnetic field sensor 80 represents any of a variety of magnetoresistive devices, AMR sensors, GMR sensors, TMR sensors, and the like that is configured to detect the direction of magnetic field 110 produced by magnet 72. Further, magnetic field sensor 80 may include a single resistor element as a dot or stripe, or magnetic field sensor 80 may include an array that includes multiple single resistor elements arranged in, for example, a Wheatstone bridge configuration.

In general, magnetic field sensor 80 is configured to sense a measurement magnetic field (e.g., magnetic field 110) in a sensing plane approximately parallel to sensing surface 82. In this example, a three-dimensional coordinate system includes an X-axis 112 (rightward and leftward on the page, a Y-axis 114 (into and out of the page), and a Z-axis 116 upward and downward on the page). The sensing plane is thus parallel to X-axis 112 and Y-axis 114, and hence perpendicular to Z-axis 116. As such, magnetic field 110 has an in-plane component, denoted by an arrow 118, in the sensing plane (parallel to X- and Y-axes 112, 114) that is “seen” or detected at sensing surface 82 of magnetic field sensor 80.

Sensor package 74 may additionally be exposed to an unwanted stray magnetic field 120, denoted by dotted lines. Shield structure 86 may be formed from a high permeability soft magnetic material (e.g., Permalloy, dynamo steel sheet, and so forth) and is suitably configured such that stray magnetic field 120 in the plane (e.g., defined by X- and Y-axes 112, 114) parallel to sensing surface 82 will be redirected inside shield structure 86 so as to reduce the influence of stray magnetic field 120 on the measurement of magnetic field 110. However, sensing surface 82 of magnetic field sensor 80 is displaced away from shield structure 86 by spacer 88, in a direction parallel to Z-axis 116 and therefore perpendicular to X- and Y-axes 112, 114. As such, the measurement field (e.g., in-plane component 118 of magnetic field 110) of magnet 72 will not be or will minimally be affected by the presence of shield structure 86.

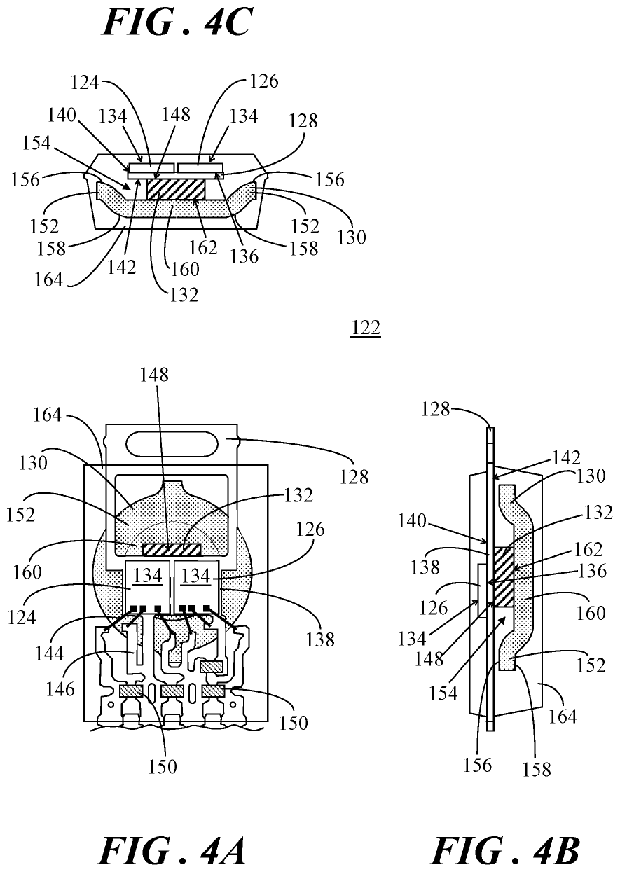

The reduced influence of stray magnetic field 120 is dependent upon the suppression factor of shield structure 86, and this suppression factor may be due at least in part upon the material properties of shield structure 86, the shape of shield structure 86, the location of shield structure 86 relative to magnetic field sensor 80, the size of magnetic field sensor 80 relative to shield structure 86, the size of shield structure 86 relative to the size of magnet 72, the location of magnetic field sensor 80 relative to magnet 72, and so forth. For example, the distance of the shield structure to the reading point of the magnetic field sensor (e.g., the sensing surface) and the distance of the shield structure to the encoder magnet may have a significant impact on the shielding capability of the shield structure and the magnetic strength of the measurement magnetic field at the reading point of the magnetic field sensor. In another example, although magnet 72 is illustrated as having a diameter (e.g., outer dimension) that is larger than the diameter (outer dimension) of shield structure 86, more effective shielding factors may be achieved when the shield diameter is larger than the diameter of magnet 72. The features that may result in a reduced influence of stray magnetic field 120 on the measurement of magnetic field 110 will be discussed below with various sensor package embodiments described in connection the subsequent FIGS. 4-15. Accordingly, any of the below described sensor packages may be implemented within system 70 in lieu of sensor package 74.

FIGS. 4A-C show top, side, and front views, respectively, of a sensor package 122 in accordance with an embodiment. More particularly, FIG. 4A shows the top view of sensor package 122, FIG. 4B shows the side view of sensor package 122, and FIG. 4C shows the front view of sensor package 122. The terms “top,” “side,” and “front” are used herein merely to distinguish the three views of sensor package 122 without necessarily requiring any particular orientation within an end use configuration.

Sensor package 122 includes two magnetic field sensors 124, 126, a lead frame 128, a shield structure 130 (stippled shading), and a spacer 132 (rightward and upward directed wide hatching). Again, shield structure 130 can be formed as a separate structure from magnetic field sensors 124, 126. Each of magnetic field sensors 124, 126 has a first surface 134 and a second surface 136 opposite the first surface 134. First surface 134 is referred to hereinafter as a sensing surface 134 since it is the magnetic sensing point. That is, the magnetic sensing elements of magnetic field sensors 124, 126 are located at sensing surface 134. Although sensor package 122 includes two magnetic field sensors 124, 126 (two sensor dies), alternative embodiments may include a single magnetic field sensor or more than two magnetic field sensors.

Lead frame 128 has a mounting area 138 characterized by a first side 140 and a second side 142 opposite the first side 140. Second surface 136 of each of magnetic field sensors 124, 126 is attached to first side 140 of mounting area 138. Bond wires 144 may electrically connect magnetic field sensor 124, 126 to leads 146 of lead frame 128. Additionally, capacitors 150 (represented by rightward and downward narrow hatching) may be connected between certain leads 146 of lead frame 128 to fulfill EMC performance requirements, provide ESD protection, and/or for bridging small interruptions of power.

In the illustrated configuration, spacer 132 may be formed from silicon or any other suitable material. Spacer 132 is interposed between second surface 136 of magnetic field sensors 124, 126 and shield structure 130. More particularly, a first spacer side 148 of spacer 132 is coupled to lead frame 128 at second side 142 of mounting area 138. Shield structure 130 includes a continuous sidewall 152 having a central cavity region 154 bounded by continuous sidewall 152. Continuous sidewall 152 has a first edge 156 and a second edge 158. In some embodiments, first edge 156 may be directly connected to second side 142 of lead frame 128. In other embodiments, first edge 156 may not be directly connected to second side 142 of lead frame 128. Shield structure 130 further includes a plate section 160 coupled to second edge 158 of continuous sidewall 152. Spacer 132 is positioned within central cavity region 154 bounded by continuous sidewall 152, with a second spacer side 162 of spacer 132 being coupled to plate section 160. Magnetic field sensors 124, 126, shield structure 130, spacer 132, mounting area 138 of lead frame 128, bond wires 144, and the ends of leads 146 to which bond wires 144 are attached may be encapsulated in a mold compound 164 to form sensor package 122.

Thus, sensing surface 134 of each of first and second magnetic field sensors 124, 126 is displaced away from shield structure 130 in a direction perpendicular to the X- and Y-axes 112, 114 (FIG. 3) as discussed above so that sensing surface 134 is positioned outside of central cavity region 154 bounded by continuous sidewall 152 in the Z-direction aligned with Z-axis 116 of FIG. 3 and toward magnet 72 (FIG. 3). Additionally, magnetic field sensors 124, 126 are smaller than shield structure 130. More particularly, sensing surfaces 134 of magnetic field sensors 124, 126 are characterized by a first total area parallel to X- and Y-axes 112, 114 and shield structure 130 is characterized by a second area aligned parallel to the first total area, the second area being greater than the first total area. As such, the magnetic point (e.g., sensing element locations at sensing surface 134) of magnetic field sensors 124, 126 are positioned above central region 154 but within the perimeter of shield structure 130.

Again, shield structure 130 may be formed from a high permeability soft magnetic material (e.g., Permalloy, dynamo steel sheet, and so forth) and is suitably configured such that stray magnetic field 120 (FIG. 3) in the plane parallel to sensing surface 134 will be redirected inside shield structure 130 so as to reduce the influence of stray magnetic field 120 on the measurement of magnetic field 110 (FIG. 3). However, sensing surface 134 of magnetic field sensors 124, 126 is displaced away from shield structure 130 by spacer 132, in a direction parallel to Z-axis 116 and therefore perpendicular to X- and Y-axes 112, 114. As such, the measurement field (e.g., in-plane component 118 of magnetic field 110) of magnet 72 (FIG. 3) will not be or will minimally be affected by the presence of shield structure 130.

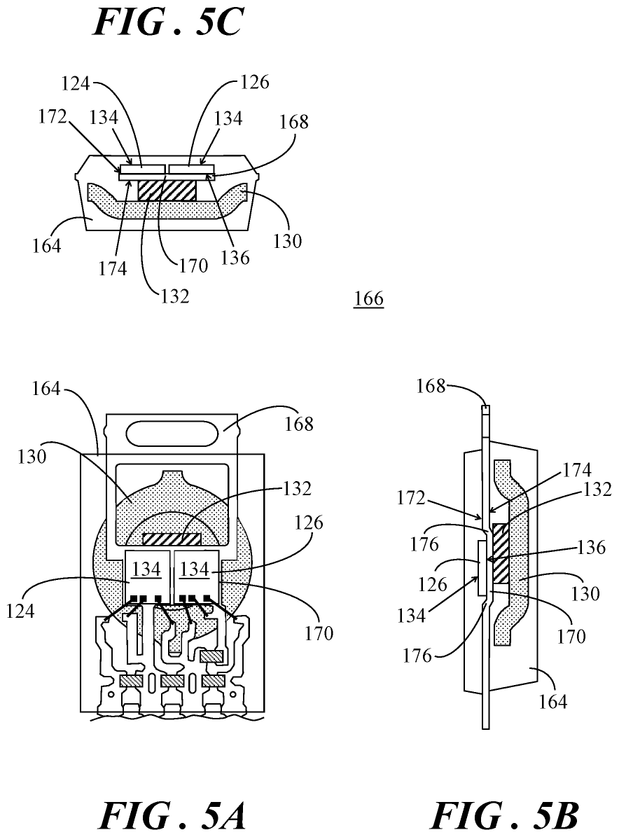

FIGS. 5A-C show top, side, and front views, respectively, of a sensor package 166 in accordance with another embodiment. More particularly, FIG. 5A shows the top view of sensor package 166, FIG. 5B shows the side view of sensor package 166, and FIG. 5C shows the front view of sensor package 166. Many of the elements of sensor package 122 (FIGS. 4A-C) are also incorporated within sensor package 166. Hence, the same reference numerals will be used for those elements that are common to both of sensor packages 122, 166, the description of those elements presented above applies equivalently to sensor package 166, and the description will not be repeated in connection with sensor package 166 in the interest of brevity.

Sensor package 166 includes magnetic field sensors 124, 126, shield structure 130, and spacer 132, as described in detail above. In accordance with this illustrated embodiment, sensor package 166 further includes a lead frame 168 disposed between magnetic field sensors 124, 126 and spacer 132. Lead frame 168 has a mounting area 170 characterized by a first side 172 and a second side 174, the second side being opposite the first side 172. Second surface 136 of magnetic field sensors 124, 126 is attached to first side 172 of mounting area 170. Mounting area 170 is disposed away from the remainder of lead frame 168 such that first side 172 of mounting area 170 is surrounded by lead frame sidewalls 176. Thus, in sensor package 166, mounting area 170 is set down toward shield structure 130 to position the magnetic field reading point (e.g., sensing surface 134) of magnetic field sensors 124, 126 closer to or inside central region 154 of shield structure 130. Such a position may enhance the stray field suppression capability of shield structure 130.

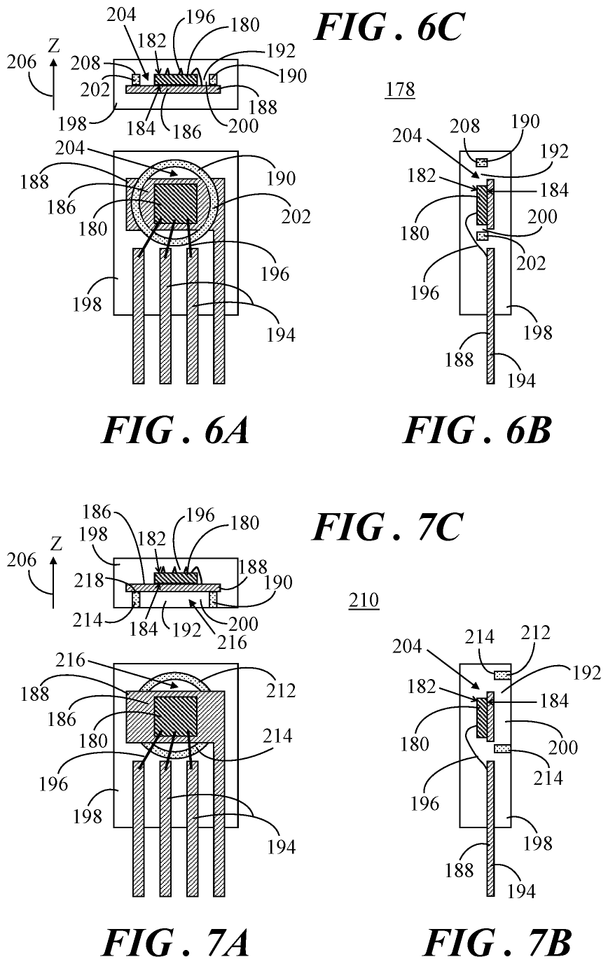

FIGS. 6A-C through FIGS. 15A-C will present sensor packages as simplified pictorial representations to show various alternative integrated shield structure configurations. As such, the same reference numerals will be used throughout the descriptions of FIGS. 6A-C through FIGS. 15A-C, with the exception of the shield structure and its associated features which will be renumbered in each of the drawings. Additionally, for consistency throughout the following descriptions of various sensor package configurations, magnetic field sensors will be represented by downward and rightward directed dark hatching, lead frames will be represented by upward and rightward directed light hatching, shield structures will be represented by a stippled pattern, and mold compound will not be shaded in order to better visualize the structures within the sensor packages.

In each of the various configurations presented below, the shield structure can be formed as a separate structure from the magnetic field sensors to provide suitable shielding or suppression of stray magnetic fields, while readily and cost effectively incorporating the shield structure into the sensor package. The position of the shield structure in relation to the magnetic field sensors, therefore, is a compromise between sufficiently shielding the stray magnetic fields without unduly suppressing the magnetic field from the encoder magnet. As such, a compromise may be achieved between optimal shielding of stray magnetic fields and cost-effective fabrication options.

FIGS. 6A-C show simplified top, side, and front views, respectively, of a sensor package 178 in accordance with another embodiment. Sensor package 178 includes a magnetic field sensor 180 having a first surface 182 and a second surface 184 opposite the first surface 182. Although magnetic field sensor 180 is described in singular form, magnetic field sensor 180 represents one or more magnetic field sensor dies. First surface 182 is the magnetic sensing point at which the magnetic sensing element(s) is located, and is thus referred to hereinafter as a sensing surface 182.

Magnetic field sensor 180 is coupled to a mounting area 186 of a lead frame 188. A shield structure 190 is spaced apart from magnetic field sensor 180 and a spacer 192 (e.g., mold compound) is interposed between magnetic field sensor 180 and shield structure 190. As shown, shield structure 190 may be positioned on the same side of lead frame 188 as magnetic field sensor 180. Magnetic field sensor 180, mounting area 186 of lead frame 188, lead ends of leads 194 of lead frame 188, bond wires 196 interconnected between leads 194 and magnetic field sensor 180, and shield structure 190 are encapsulated in a mold compound 198. Hence, in the illustrated example, spacer 192 includes a portion 200 of mold compound 198 located between magnetic field sensor 180 and shield structure 190.

Shield structure 190 includes a continuous sidewall 202 having a central region 204 bounded by continuous sidewall 202. Portion 200 of mold compound 198 (as spacer 192) is surrounded by continuous sidewall 202. That is, spacer 192 is located within the perimeter of sidewall 202. In this embodiment, shield structure 190 is generally ring shaped, and does not include a plate section as shown in FIGS. 3-5. Nevertheless, since sidewall 202 is continuous (i.e., uninterrupted), stray magnetic field 120 (FIG. 3) can be redirected through shield structure 190 and around magnetic field sensor 180.

It can be observed that sensing surface 182 of magnetic field sensor 180 is exposed from shield structure 190. In some embodiments, sensing surface 182 may be positioned outside of central region 204 bounded by continuous sidewall 202 in a direction perpendicular to sensing surface 182. That is, sensing surface 182 of magnetic field sensor 180 may be disposed in a Z-direction 206 above a top edge 208 of continuous sidewall 202 in order to suitably position the sensing point of magnetic field sensor 180 in proximity to magnet 72 (FIG. 3) of system 70 (FIG. 3). In other embodiments, sensing surface 182 may be approximately flush with top edge 208 of continuous sidewall 202.

FIGS. 7A-C show simplified top, side, and front views, respectively, of a sensor package 210 in accordance with another embodiment. FIG. 7A shows the top view of sensor package 210, FIG. 7B shows the side view of sensor package 210, and FIG. 7C shows the front view of sensor package 210. Sensor package 210 includes magnetic field sensor 180 coupled to mounting area 186 of a lead frame 188. A shield structure 212 is spaced apart from magnetic field sensor 180 and spacer 192 is interposed between magnetic field sensor 180 and shield structure 212. As shown, shield structure 212 may be positioned on the opposite side of lead frame 188 from magnetic field sensor 180. Magnetic field sensor 180, mounting area 186 of lead frame 188, lead ends of leads 194 of lead frame 188, bond wires 196 interconnected between leads 194 and magnetic field sensor 180, and shield structure 212 are encapsulated in mold compound 198. Hence, in the illustrated example, spacer 192 includes portion 200 of mold compound 198 located below mounting area 186 of lead frame 188 and circumscribed by shield structure 212.

Shield structure 212 includes a continuous sidewall 214 having a central region 216 bounded by continuous sidewall 214. Portion 200 of mold compound 198 (as spacer 192) is surrounded by continuous sidewall 214. That is, spacer 192 is located within the perimeter of sidewall 214. In this embodiment, shield structure 212 is generally ring shaped, and does not include a plate section as shown in FIGS. 3-5. Nevertheless, since sidewall 214 is continuous (i.e., uninterrupted), stray magnetic field 120 (FIG. 3) can be redirected through shield structure 212 and around magnetic field sensor 180.

It can be observed that the entire magnetic field sensor 180 and sensing surface 182 of magnetic field sensor 180 is exposed from shield structure 212. In particular, magnetic field sensor 180 is positioned outside of central region 216 bounded by continuous sidewall 218 in Z-direction 206 above a top edge 218 of continuous sidewall 214 in order to suitably position the sensing point of magnetic field sensor 180 in proximity to magnet 72 (FIG. 3) of system 70 (FIG. 3).

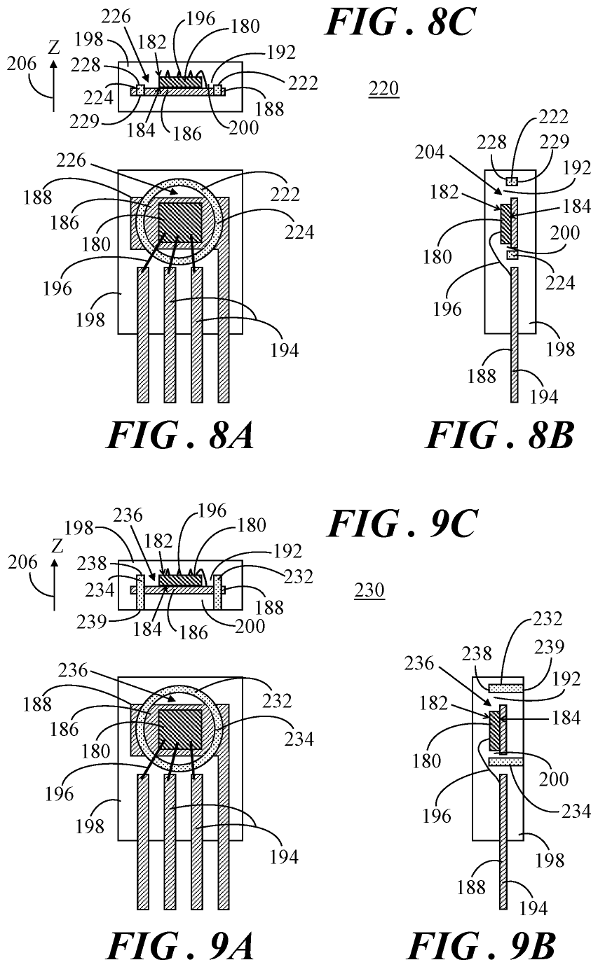

FIGS. 8A-C show simplified top, side, and front views, respectively, of a sensor package 220 in accordance with another embodiment. FIG. 8A shows the top view of sensor package 220, FIG. 8B shows the side view of sensor package 220, and FIG. 8C shows the front view of sensor package 220. Sensor package 220 includes magnetic field sensor 180 coupled to mounting area 186 of a lead frame 188. A shield structure 222 is spaced apart from magnetic field sensor 180 and spacer 192 is interposed between magnetic field sensor 180 and shield structure 222. As shown, shield structure 222 may be formed to extend through lead frame 188 such that a top edge 228 of shield structure 222 is located on the side of lead frame 188 at which magnetic field sensor 180 and a bottom edge 229 of shield structure 222 is located on the opposite side of lead frame 188. Magnetic field sensor 180, mounting area 186 of lead frame 188, lead ends of leads 194 of lead frame 188, bond wires 196 interconnected between leads 194 and magnetic field sensor 180, and shield structure 222 are encapsulated in mold compound 198. Hence, in the illustrated example, spacer 192 includes portion 200 of mold compound 198 located both above and below mounting area 186 of lead frame 188 that is circumscribed by shield structure 222.

Shield structure 222 includes a continuous sidewall 224 having a central region 226 bounded by continuous sidewall 224. Portion 200 of mold compound 198 (as spacer 192) is surrounded by continuous sidewall 224. That is, spacer 192 is located within the perimeter of sidewall 224. In this embodiment, shield structure 222 is generally ring shaped. Since sidewall 214 is continuous (i.e., uninterrupted), stray magnetic field 120 (FIG. 3) can be redirected through shield structure 222 and around magnetic field sensor 180. Sensing surface 182 of magnetic field sensor 180 is exposed from shield structure 222. In particular, although the lower portion of magnetic field sensor 180 is located within the perimeter of shield structure 222, the upper portion of magnetic field sensor 180 including sensing surface 182 is positioned outside of central region 216 bounded by continuous sidewall 224 in Z-direction 206 above top edge 228 of continuous sidewall 224 in order to suitably position the sensing point of magnetic field sensor 180 in proximity to magnet 72 (FIG. 3) of system 70 (FIG. 3).

FIGS. 9A-C show simplified top, side, and front views, respectively, of a sensor package 230 in accordance with another embodiment. FIG. 9A shows the top view of sensor package 230, FIG. 9B shows the side view of sensor package 230, and FIG. 9C shows the front view of sensor package 230. Sensor package 230 includes magnetic field sensor 180 coupled to mounting area 186 of a lead frame 188. A shield structure 232 is spaced apart from magnetic field sensor 180 and spacer 192 is interposed between magnetic field sensor 180 and shield structure 232. As shown, shield structure 232 again may be formed to extend through lead frame 188 such that a top edge 238 of shield structure 232 is located on the side of lead frame 188 at which magnetic field sensor 180 and a bottom edge 239 of shield structure 222 is located on the opposite side of lead frame 188.

Magnetic field sensor 180, mounting area 186 of lead frame 188, lead ends of leads 194 of lead frame 188, bond wires 196 interconnected between leads 194 and magnetic field sensor 180, and shield structure 232 are encapsulated in mold compound 198. However, bottom edge 239 may be exposed from mold compound 198 in some embodiments. Hence, in the illustrated example, spacer 192 includes portion 200 of mold compound 198 located both above and below mounting area 186 of lead frame 188 and circumscribed by shield structure 232.

Shield structure 232 includes a continuous sidewall 234 having a central region 236 bounded by continuous sidewall 234. Portion 200 of mold compound 198 (as spacer 192) is surrounded by continuous sidewall 234. That is, spacer 192 is located within the perimeter of sidewall 234. In this embodiment, shield structure 222 is generally ring shaped. Since sidewall 234 is continuous (i.e., uninterrupted), stray magnetic field 120 (FIG. 3) can be redirected through shield structure 232 and around magnetic field sensor 180. Sensing surface 182 of magnetic field sensor 180 is exposed from shield structure 232. In particular, although the lower portion of magnetic field sensor 180 is located within the perimeter of shield structure 232, sensing surface 182 of magnetic field sensor 180 is positioned flush with top edge 238, inside or outside of central region 236 bounded by continuous sidewall 234 of shield structure 232 in Z-direction 206 above top edge 238 of continuous sidewall 224 in order to suitably position the sensing point of magnetic field sensor 180 in proximity to magnet 72 (FIG. 3) of system 70 (FIG. 3).

Although shield structure 232 is illustrated as a single shield, a portion of which extends through lead frame 188, as shown in FIG. 9C, it should be understood that in alternative embodiments, a shield structure may include multiple separate shield portions. For example, a first shield portion may be located on the same side of the lead frame as the magnetic field sensor (as in FIGS. 6A-C) and second shield portion may be located on the opposite side of the lead frame as the magnetic field sensor (as in FIGS. 7A-C).

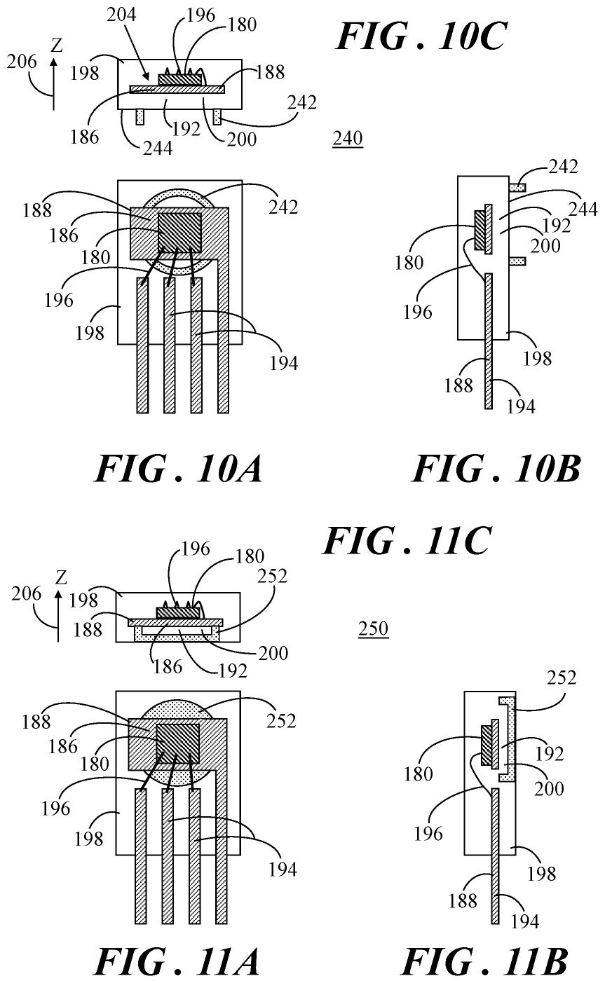

FIGS. 10A-C show simplified top, side, and front views, respectively, of a sensor package 240 in accordance with another embodiment. FIG. 10A shows the top view of sensor package 240, FIG. 10B shows the side view of sensor package 240, and FIG. 10C shows the front view of sensor package 240. Sensor package 240 includes magnetic field sensor 180 coupled to mounting area 186 of a lead frame 188. A shield structure 242 is spaced apart from magnetic field sensor 180 and spacer 192 is interposed between magnetic field sensor 180 and shield structure 242. In this configuration, magnetic field sensor 180, mounting area 186 of lead frame 188, lead ends of leads 194 of lead frame 188, and bond wires 196 interconnected between leads 194 and magnetic field sensor 180 are encapsulated in mold compound 198. Additionally, shield structure 242 may be attached to a bottom surface 244 of mold compound 198. Hence, in the illustrated example, spacer 192 includes portion 200 of mold compound 198 located below mounting area 186 of lead frame 188.

FIGS. 11A-C show simplified top, side, and front views, respectively, of a sensor package 250 in accordance with another embodiment. FIG. 11A shows the top view of sensor package 250, FIG. 11B shows the side view of sensor package 250, and FIG. 11C shows the front view of sensor package 250. Sensor package 250 includes magnetic field sensor 180 coupled to mounting area 186 of a lead frame 188. A shield structure 252 is spaced apart from magnetic field sensor 180 and spacer 192 is interposed between magnetic field sensor 180 and shield structure 252. In this configuration, magnetic field sensor 180, mounting area 186 of lead frame 188, lead ends of leads 194 of lead frame 188, bond wires 196 interconnected between leads 194 and magnetic field sensor 180, and shield structure 252 are encapsulated in mold compound 198. The configuration of FIGS. 11A-C is similar to the configuration of FIGS. 4A-C, with the exception being that spacer 192 is portion 200 of mold compound 198 in lieu of the separate material spacer 132 (FIGS. 4A-C). Hence, further description is not provided herein for brevity.

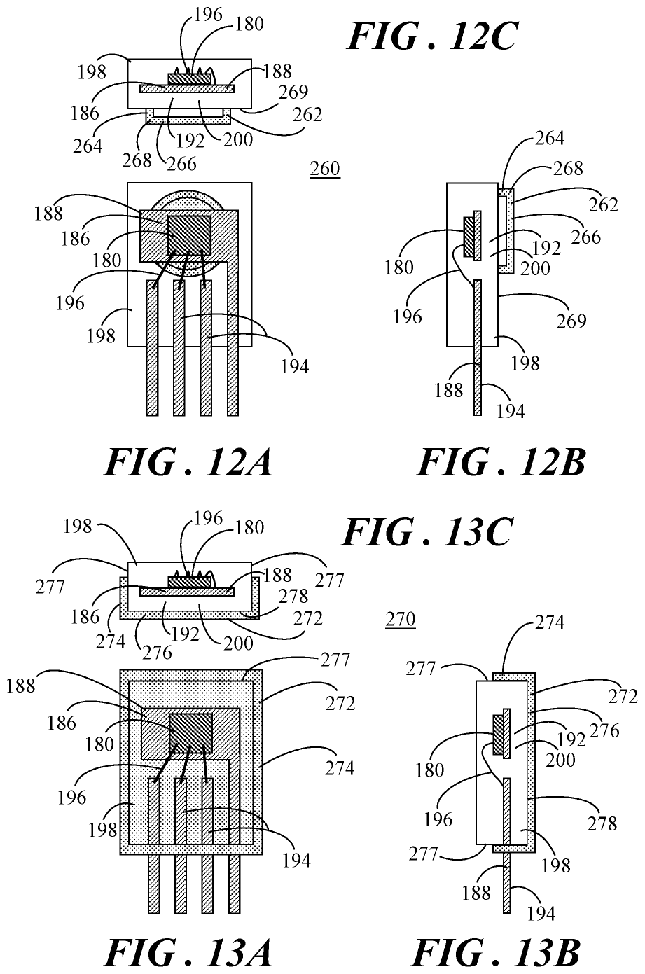

FIGS. 12A-C show simplified top, side, and front views, respectively, of a sensor package 260 in accordance with another embodiment. FIG. 12A shows the top view of sensor package 260, FIG. 12B shows the side view of sensor package 260, and FIG. 12C shows the front view of sensor package 260. Sensor package 260 includes magnetic field sensor 180 coupled to mounting area 186 of a lead frame 188. A shield structure 262 is spaced apart from magnetic field sensor 180 and spacer 192 is interposed between magnetic field sensor 180 and shield structure 262. In this configuration, magnetic field sensor 180, mounting area 186 of lead frame 188, lead ends of leads 194 of lead frame 188, and bond wires 196 interconnected between leads 194 and magnetic field sensor 180 are encapsulated in mold compound 198. In this example, shield structure 262 includes a continuous sidewall 264 and a plate section 266 coupled to a bottom edge 268 of continuous sidewall 264. Additionally, shield structure 262 may be attached to a bottom surface 269 of mold compound 198. Hence, in the illustrated example, spacer 192 includes portion 200 of mold compound 198 located below mounting area 186 of lead frame 188.

FIGS. 13A-C show simplified top, side, and front views, respectively, of a sensor package 270 in accordance with another embodiment. FIG. 13A shows the top view of sensor package 270, FIG. 13B shows the side view of sensor package 270, and FIG. 13C shows the front view of sensor package 270. Sensor package 270 includes magnetic field sensor 180 coupled to mounting area 186 of a lead frame 188. A shield structure 272 is spaced apart from magnetic field sensor 180 and spacer 192 is interposed between magnetic field sensor 180 and shield structure 272. In this configuration, magnetic field sensor 180, mounting area 186 of lead frame 188, lead ends of leads 194 of lead frame 188, and bond wires 196 interconnected between leads 194 and magnetic field sensor 180 are encapsulated in mold compound 198. In this example, shield structure 272 includes a continuous sidewall 274 and a plate section 276. Continuous sidewall 274 and plate section 276 of shield structure 272 are attached to exterior sidewalls 277 and a bottom surface 278, respectively, of mold compound 198. Thus, continuous sidewall 274 is exposed from and surrounds an outer perimeter of mold compound 198. In the illustrated example, spacer 192 includes portion 200 of mold compound 198 located below mounting area 186 of lead frame 188.

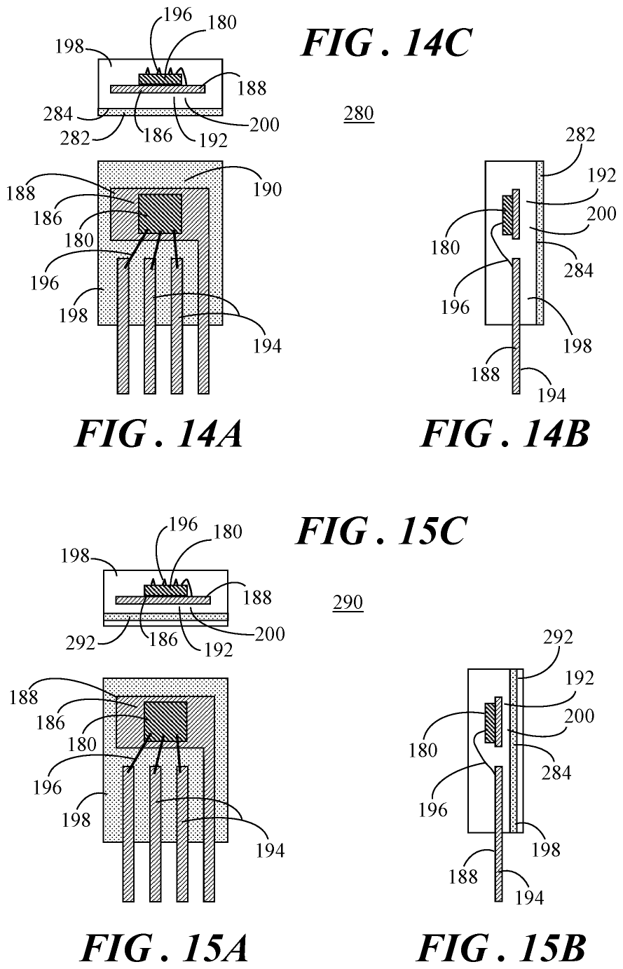

FIGS. 14A-C show simplified top, side, and front views, respectively, of a sensor package 280 in accordance with another embodiment. FIG. 14A shows the top view of sensor package 280, FIG. 14B shows the side view of sensor package 280, and FIG. 14C shows the front view of sensor package 280. Sensor package 280 includes magnetic field sensor 180 coupled to mounting area 186 of a lead frame 188. A shield structure 282 is spaced apart from magnetic field sensor 180 and spacer 192 is interposed between magnetic field sensor 180 and shield structure 282. Magnetic field sensor 180, mounting area 186 of lead frame 188, lead ends of leads 194 of lead frame 188, and bond wires 196 interconnected between leads 194 and magnetic field sensor 180 are encapsulated in mold compound 198. In this example, shield structure 282 includes a generally flat plate section without the continuous sidewall structure discussed above. Shield structure 282 is attached to a bottom surface 284 of mold compound 198. In the illustrated example, spacer 192 includes portion 200 of mold compound 198 located below mounting area 186 of lead frame 188.

FIGS. 15A-C show simplified top, side, and front views, respectively, of a sensor package 290 in accordance with another embodiment. FIG. 15A shows the top view of sensor package 290, FIG. 15B shows the side view of sensor package 290, and FIG. 15C shows the front view of sensor package 290. Sensor package 290 includes magnetic field sensor 180 coupled to mounting area 186 of a lead frame 188. A shield structure 292 is spaced apart from magnetic field sensor 180 and spacer 192 is interposed between magnetic field sensor 180 and shield structure 292. Magnetic field sensor 180, mounting area 186 of lead frame 188, lead ends of leads 194 of lead frame 188, bond wires 196 interconnected between leads 194 and magnetic field sensor 180, and shield structure 292 are encapsulated in mold compound 198. In this example, shield structure 292 includes a generally flat plate section without the continuous sidewall structure discussed above. In the illustrated example, spacer 192 includes portion 200 of mold compound 198 located below mounting area 186 of lead frame 188.

Various embodiments of shield structures integrated into magnetic field sensor packages have been described herein in connection with FIGS. 4-15. Those of skill in the art would understand, based on the description herein, that alternative shield structures integrated into sensor packages may have differing shapes then those shown. For example, a rectangular shield structure may be implemented in lieu of the generally elliptical structures may alternatively be implemented. Further, although the shield structures illustrated above are either encapsulated in mold compound or attached to an outer surface of the sensor package, a shield structure may be physically separate from the mold compound, but in close enough proximity to the magnetic field sensors to effectively suppress stray magnetic fields. Still further, as mentioned above, a shield structure may include multiple separate shield structures In an example, a first shield structure may be attached to a first (top) side of a lead frame and a second shield structure may be attached to a second (bottom) side of the lead frame. Additionally, spacer structures and materials other than those shown may alternatively be incorporated. For example, although spacers are discussed above as being silicon and/or mold compound, in alternative embodiments, spacers may be the thickness of the lead frame and/or an air gap. And, again, in a system configuration the encoder magnet may have an outer dimension that is smaller than the outer dimension of the shield structure to provide effective stray field suppression without unduly suppressing the detection magnetic field from encoder magnet.

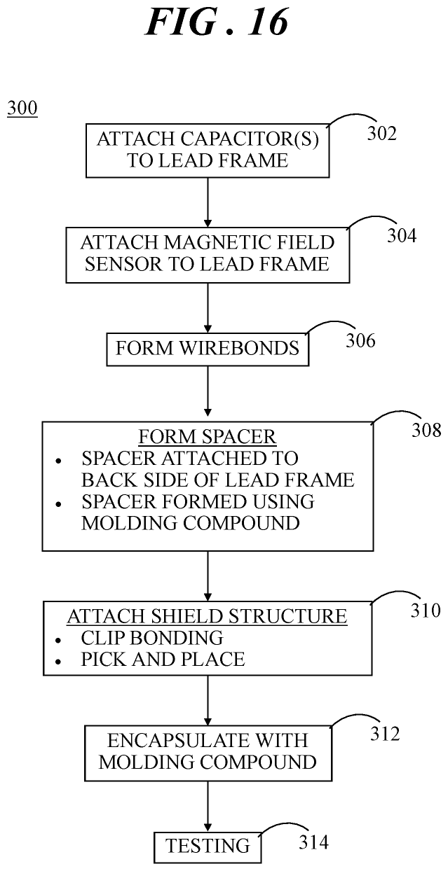

Referring now to FIG. 16, FIG. 16 shows a flowchart of a process 300 for manufacturing a sensor package with an integrated shield structure in accordance with another embodiment. Process 300 summarizes operations that may be performed to integrate a shield structure into a magnetic field sensor process. Process 300 will be described in connection with the manufacture of sensor package 122. Hence, reference should be made concurrently with FIGS. 4A-C along with the discussion of manufacturing process 300 of FIG. 16.

At a block 302, capacitors (e.g., capacitors 150) may be attached to the lead frame (e.g., lead frame 128). At a block 304, one or more magnetic field sensors (e.g., magnetic field sensors 124, 126) are attached to the lead frame. At a block 306, bond wires (e.g. bond wires 144) may be formed between the die pads on the magnetic field sensors and the leads (e.g., leads 146) of the lead frame. At a block 308, the spacer may be formed. For example, spacer 132 may be attached to the back side (e.g., second side 142) of the lead frame using a die attach process or using a pick and place process. In other embodiments, the spacer may be formed using a mold compound during the encapsulation operations of block 312, discussed below), or during a separate partial deposition of the mold compounds.

In a block 310, the shield structure (e.g., shield structure 130) is attached. For example, the shield structure may be attached using a conventional pick and place process. In another example, the shield structure may be attached using a clip bonding process in which prefabricated shield structures may be provided in single or multiple track lead frames, and the shield structures are cut out of the frames and placed on the device by a standard clip bonder. In a block 312, the structure is encapsulated with a mold compounded (e.g., mold compound 164) to form the sensor package (e.g., sensor package 122). Thereafter, the sensor package may undergo testing, further packaging, or any other additional process operations.

Embodiments described herein entail, sensor packages with integrated magnetic field shield structures, a system that includes such sensor packages and methodology for manufacturing the sensor packages with integrated magnetic shield structures. An embodiment of a sensor package comprises a magnetic field sensor having a first surface and a second surface opposite the first surface, the first surface being a sensing surface of the magnetic field sensor, a shield structure spaced apart from the magnetic field sensor, and a spacer interposed between the magnetic field sensor and the shield structure, wherein the shield structure is configured to suppress stray magnetic fields in a plane parallel to a first axis and a second axis, the first and second axes being parallel to the sensing surface of the magnetic field sensor and perpendicular to one another.

An embodiment of a system comprises an encoder magnet configured to produce a measurement magnetic field and a sensor package in proximity to the encoder magnet. The sensor package comprises a magnetic field sensor having a first surface and a second surface opposite the first surface, the first surface being a sensing surface of the magnetic field sensor for detecting the measurement magnetic field, a shield structure spaced apart from magnetic field sensor, and a spacer interposed between the magnetic field sensor and the shield structure, wherein the shield structure is configured to suppress stray magnetic fields in a plane parallel to a first axis and a second axis, the first and second axes being parallel to the sensing surface of the magnetic field sensor and perpendicular to one another.

An embodiment of a method of manufacturing a sensor package comprises attaching a magnetic field sensor to a first side of a mounting area of a lead frame, the magnetic field sensor having a first surface and a second surface opposite the first surface, the first surface being a sensing surface of the magnetic field sensor, and the second surface of the magnetic field sensor being attached to the first side of the mounting area. The method further comprises coupling a first spacer side of a spacer to a second side of the mounting area of the lead frame, and coupling a shield structure to a second spacer side of the spacer such that the spacer is interposed between the magnetic field sensor and the shield structure, wherein the shield structure is configured to suppress stray magnetic fields in a plane parallel to a first axis and a second axis, the first and second axes being parallel to the sensing surface of the magnetic field sensor and perpendicular to one another, and the sensing surface of the magnetic field sensor is displaced away from the shield structure in a direction perpendicular to the first and second axes.

Thus, a sensor package includes an integrated magnetic field shield structure that enables measurement of a magnetic field in the plane of a magnetic field sensor while suppressing stray magnetic fields in the plane of the magnetic field sensor. More particularly, a sensor package includes one or more magnetic field sensors partially encompassed by a magnetic field shield structure. The geometric configuration of the shield structure and the location of the shield structure within a sensor package can be varied to provide shielding or suppression of stray magnetic fields with minor or little adverse impact to the measurement magnetic field acting on magnetic sensor components. Further, the shield structure can be formed as a separate structure from the magnetic field sensors to enable straightforward incorporation into a sensor package. The position of the shield structure in relation to the magnetic field sensors, therefore, may enable sufficient shielding of the stray magnetic fields without unduly suppressing the magnetic field from, for example, an encoder magnet. Accordingly, a compromise may be achieved between optimal passive stray field suppression (with no additional electronic circuitry) and cost-effective, accurate manufacturing options. Still further, the magnetic field sensor package can be integrated in various system configurations to satisfy automotive requirements in, for example, throttle valves, pedals, steering wheels, brushless direct current (BLDC) motors, and so forth.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A sensor package comprising:
a magnetic field sensor having a first surface and a second surface opposite the first surface, the first surface being a sensing surface of the magnetic field sensor;
a shield structure spaced apart from the magnetic field sensor and formed as a separate structure from the magnetic field sensor; and
a spacer interposed between the magnetic field sensor and the shield structure, wherein the shield structure is configured to suppress stray magnetic fields in a plane parallel to a first axis and a second axis, the first and second axes being parallel to the sensing surface of the magnetic field sensor and perpendicular to one another.

2. The sensor package of claim 1 wherein the sensing surface of the magnetic field sensor is displaced away from the shield structure in a direction perpendicular to the first and second axes.

3. The sensor package of claim 1 further comprising a lead frame having a mounting area characterized by a first side and a second side, the second side being opposite the first side, the second surface of the magnetic field sensor being attached to the first side of the mounting area and a first spacer side of the spacer being coupled to the lead frame at the second side of the mounting area.

4. The sensor package of claim 3 wherein the shield structure is coupled to a second spacer side of the spacer.

5. The sensor package of claim 3 further comprising a mold compound encapsulating the magnetic field sensor, the mounting area of the lead frame, and the shield structure, wherein the spacer includes a portion of the mold compound between the second side of the lead frame and the shield structure.

6. The sensor package of claim 3 further comprising a mold compound encapsulating the magnetic field sensor and the mounting area of the lead frame, wherein the shield structure is exposed at an outer surface of the mold compound.

7. The sensor package of claim 1 further comprising a lead frame having a mounting area characterized by a first side and a second side, the second side being opposite the first side, wherein mounting area is disposed away from the remainder of the lead frame such that the first side of the mounting area is surrounded by lead frame sidewalls, and the second surface of the magnetic field sensor is attached to the first side of the mounting area.

8. The sensor package of claim 1 wherein the shield structure comprises a continuous sidewall having a central region bounded by the continuous sidewall and the spacer is positioned within the central region and is surrounded by the continuous sidewall.

9. The sensor package of claim 8 wherein the continuous sidewall has a first edge and a second edge, the shield structure further comprises a plate section coupled to the first and second edges of the continuous sidewall, and the spacer is coupled to the plate section.

10. The sensor package of claim 8 wherein the sensing surface of the magnetic field sensor is positioned inside of or outside of the central region bounded by the continuous sidewall in a direction perpendicular to the first and second axes.

11. The sensor package of claim 1 wherein:
each of the first and second surfaces of the magnetic field sensor is characterized by a first area parallel to the first and second axes; and
the shield structure is characterized by a second area aligned parallel to the first area, the second area being greater than the first area.

12. A system comprising:
an encoder magnet configured to produce a measurement magnetic field; and
a sensor package in proximity to the encoder magnet, the sensor package comprising:
a magnetic field sensor having a first surface and a second surface opposite the first surface, the first surface being a sensing surface of the magnetic field sensor for detecting the measurement magnetic field;
a shield structure spaced apart from magnetic field sensor and formed as a separate structure from the magnetic field sensor; and
a spacer interposed between the magnetic field sensor and the shield structure, wherein the shield structure is configured to suppress stray magnetic fields in a plane parallel to a first axis and a second axis, the first and second axes being parallel to the sensing surface of the magnetic field sensor and perpendicular to one another.

13. The system of claim 12 wherein the encoder magnet is configured to rotate about an axis of rotation, and each of the encoder magnet and the magnetic field sensor is centered at the axis of rotation.

14. The system of claim 12 wherein:
each of the first and second surfaces of the magnetic field sensor is characterized by a first area parallel to the first and second axes; and
the shield structure is characterized by a second area aligned parallel to the first area, the second area being greater than the first area.

15. The system of claim 12 wherein the sensing surface of the magnetic field sensor is displaced away from the shield structure toward the encoder magnet in a direction perpendicular to the first and second axes.

16. The system of claim 12 further comprising a lead frame having a mounting area characterized by a first side and a second side, the second side being opposite the first side, the second surface of the magnetic field sensor being attached to the first side of the mounting area and a first spacer side of the spacer being coupled to the lead frame at the second side of the mounting area.

17. The system of claim 12 wherein the shield structure comprises a continuous sidewall having a central region bounded by the continuous sidewall, the spacer is positioned within the central region and is surrounded by the continuous sidewall, and the sensing surface of the magnetic field sensor is positioned outside of the central region bounded by the continuous sidewall toward the encoder magnet in a direction perpendicular to the first and second axes.

18. The system of claim 17 wherein the continuous sidewall has a first edge and a second edge, the shield structure further comprises a plate section coupled to the second edge of the continuous structure sidewall, and the spacer is coupled to the plate section.

19. A method of manufacturing a sensor package comprising:
attaching a magnetic field sensor to a first side of a mounting area of a lead frame, the magnetic field sensor having a first surface and a second surface opposite the first surface, the first surface being a sensing surface of the magnetic field sensor, and the second surface of the magnetic field sensor being attached to the first side of the mounting area;
coupling a first spacer side of a spacer to a second side of the mounting area of the lead frame; and
coupling a shield structure to a second spacer side of the spacer such that the spacer is interposed between the magnetic field sensor and the shield structure, wherein:
the shield structure is configured to suppress stray magnetic fields in a plane parallel to a first axis and a second axis, the first and second axes being parallel to the sensing surface of the magnetic field sensor and perpendicular to one another; and
the sensing surface of the magnetic field sensor is displaced away from the shield structure in a direction perpendicular to the first and second axes.

20. The method of claim 19 further comprising encapsulating the magnetic field sensor, the mounting area of the lead frame, the spacer, and the shield structure in a mold compound, wherein the shield structure is at least partially encapsulated in the mold compound.
